(19) United States
(12) Patent Application Publication
(10) Pub. No.: US 2010/0283638 A1
(43) Pub. Date: Nov. 11, 2010

(54) WORLD'S FASTEST MULTI-TAP PHONE AND CONTROL MEANS

(76) Inventor: James W. Burrell, IV, Union, NJ (US)

Correspondence Address: Ezra Sutton, P.A.;Suite 201, Plaza 9, 900 Route 9, Woodbridge, NJ, 07095-1024, US

(21) Appl. No.: 12/435,637

(22) Filed: May 5, 2009

(51) Int. Cl. H03M 11/02

(52) U.S. Cl. 341/22

(57) ABSTRACT

This invention relates to a multi-tap and combinational alphanumeric data entry on a 12 key device. The [1] key on is labeled with the “.QZ”. Numbers are produced by activating ten numbered keys. Activating the [#] key backspaces. Activating the [*] key one or more times enters an alphabet mode. Activating [1]-[9] keys once produces left data, twice produces middle data and three times produces right data. Activating the [1] then [*] keys produces the “-” dash. Alternatively, simultaneously activating [1]-[9] keys and a left [*] key produces left data, simultaneously activating [1]-[9] keys and a middle [0] key produces middle data and simultaneously activating [1]-[9] keys and a right [#] key produces right data. Activating the [#] key enters a data character for the next data entry on the same previously activated key. Activating the [*] key, after entering a data character, produces the shift function. Activating the [*] key twice produces the backspace function. Activating the [0] key produces a space. Activating the [0] key twice produces a Tab or Enter function. Activating the [#] key twice re-enters the number mode. Activating the [#] and [*] keys enters a first punctuation/symbol mode, where activating [1]-[9] or [0] keys produces left data. Activating the [#] and [*] keys and the [*] again enters a second punctuation/symbol mode, where activating [1]-[9] or [0] keys produces middle data. Activating the [#] and [*] keys and the [*] two more times enters a third punctuation/symbol mode, where activating [1]-[9] or [0] keys produces right data. The alphabetic mode is automatically re-entered into after the punctuation mark or symbol is produced. An entered punctuation mark is followed by a space. Activating the [*] key after the punctuation mark and space is produced, deletes the space after the punctuation mark. Activating the [0] key after a period and space is produced, deletes the space after the period. Simultaneous two key entry increases data input speed by reducing the amount of entries required.

### FIELD OF THE INVENTION

The present invention relates to a way of using a twelve sensor keypad for complete alphanumeric data entry, preferably using a multi-tap data entry method. The twelve sensor keypad can also be used for as a sequential or simultaneous data entry method for complete alphanumeric data entry.

### BACKGROUND OF THE INVENTION

The twelve button touch-tone telephone keypad arrangement and twelve pairs of tones produced by independently depressing any one of the twelve buttons have become the standard throughout the world. Since the advent of the twelve key push-button telephone arrangement, many have tried to produce alphanumeric text and control means using only twelve buttons. In the telephony industry, the twelve binary key (four high/three wide) push-button telephone keypad arrangement with twenty-four letters of the alphabet, excluding the “Q” and “Z”, arranged in groups of threes, located on the faces of the keys numbered two “2” through nine “9”, or the twenty-six letters of an alphabet arranged in groups of threes, located on the faces of the keys numbered one “1” through nine “9”. The actuation of any one of the twelve keys, produces an analog, dual tone multifrequency signal (DTMF), which is a combination of two analog tones. The telephone system hardware then converts the analog DTMF tones into a digital signal for processing, digital phones being the exception. In the past, the “Q” and “Z” have been located on the face of the keys in a few different locations. The most common way in the past, is where the “Q” and “Z” are located on the “1” key. Digital cell phones replace DTMF tones with a digital equivalent. On cell phones the “Q” is on the [7] key (PQRS) and the “Z” is on the [9] key (WXYZ).

U.S. Pat. No. 3,675,513 to James Flanagan, et al. discloses a communication system for exchanging alphanumeric information. Flanagan positions from left to right; The “Q”, “Z” and period “.” on the “1” key. The “Q” is produced by actuating the “1” key, followed by the actuation of the “0” key. The “Z” is produced by actuating the “1” key twice, followed by the actuation of the “0” key. The period “.” is produced by actuating the “1” key three times, followed by the actuation of the “0” key.

U.S. Pat. No. 4,012,599 to Jerome Meyer discloses a communicator and encoding scheme. Meyer positions from left to right; The period “.”, “Q” and “Z” on the “1” key. The period “.” is produced by actuating the “*” key, followed by the actuation of the “1” key. The “Q” is produced by actuating the “0” key, followed by the actuation of the “1” key. The “Z” is produced by actuating the “#” key, followed by the actuation of the “1” key.

U.S. Pat. No. 4,427,848 to Peter Tsakanikas discloses an alphanumeric data transmission system. Tsakanikas positions from left to right; the “Q”, “Z” and hyphen on the “1” key, although there is no coding scheme to layout to figure out actuation combinations for data representation. Single actuation is used for the left data position, double actuation is used for the middle data position and triple actuation is used for the right data position to produce the desired alphabetic data.

U.S. Pat. No. 4,440,977 to John Pao, et al. discloses a sequential twelve key apparatus. Pao positions from left to right; the period “.”, “Q” and “Z” on the “1” key. The period “.” is produced by actuating the “1” key, followed by the actuation of the “*” key. The “Q” is produced by actuating the “1” key, followed by the actuation of the “0” key. The “Z” is produced by actuating the “1” key, followed by the actuation of the “#” key.

U.S. Pat. No. 4,532,378 to Yasunoba Nakayama, et al. discloses a telephone apparatus for alphanumeric data entry. Nakayama positions from left to right; the “Q”, “Z” and period “.” on the “1” key. Single key actuation for the left data position, double actuation for the middle data position and triple actuation for the right data position, followed by the actuation of the “0” key, to produce the desired alphabetic data.

U.S. Pat. No. 4,585,908 to Louis Smith discloses a data entry and display circuit. Smith represents from left to right; the “Q”, a “(blank)” and a “Z” on the “1” key. The “Q” is produced by actuating the “1” key, followed by the actuation of the “#” key. The unfilled data position between the “Q” and “Z”, referred to as “(blank)”, is not used for anything. The “Z” is produced by actuating the “1” key, followed by the actuation of the “#” key. In Smith's patent application explanation, all numbers require double actuation of the numeric key to produce a number. Unlike this present invention and application, numeric data is produced by single number key actuations, while in a single key number mode. Smith also does not explain or claim a space, only cursor movement, and claims a circuit requiring an actuation of a key for an unspecified predetermined duration, along with a second key actuation, with a second unspecified predetermined duration of actuation. There is no conflict in what Smith claims in U.S. Pat. No. 4,585,908, to what is claimed in this patent application.

U.S. Pat. No. 4,650,927 to Leland James discloses a processor-assisted system for communicating using a telephone. James positions from left to right; the “Q” and “Z” on the “1” key. The “Q” is produced by actuating the “1” key. The “Z” is produced by actuating the “1” key. When the alphabetic word is completed, the user actuates the key as a space, which sends the alphabetic data word to a computer to decipher what the word is.

U.S. Pat. No. 4,674,112 to George Kondraske, et al. discloses a communication apparatus including a method of use. Kondraske positions from left to right; the “Q”, “Z” and apostrophe “'” on the “1” key. The “Q” is produced by actuating the “1” key. The “Z” is produced by actuating the “1” key. When the alphabetic word is completed, the user actuates the “*” key as a space, which sends the alphabetic data word to a computer to decipher what the word is.

U.S. Pat. No. 4,737,980 to William Curtin, et al. discloses a method and apparatus for inputting data into a computer. Curtin positions from left to right; the “Q”, “Z” and a box(?) on the “1” key. Three alphabetic letters and the number on the key face are all represented by the same key actuation. A predetermined probability algorithm guesses what type of data the user entered into the phone/computer terminal.

U.S. Pat. No. 4,918,721 to Kazuo Hashimoto discloses a phone capable of producing upper-case and lower-case letters. Hasimoto positions from left to right; the “Q”, “Z” and “space” on the number “1” key. Two methods of data entry are disclosed. In the first, the “Q” is produced by actuating the “#” key, followed by the actuation the “1” key. The “Z” is produced by actuating the “#” key twice, followed by the actuation of the “1” key. The “space” is produced by actuating the “#” key three times, followed by the actuation of the “1” key. In the second method of data entry, the “Q” is produced by actuating the “1” key twice, followed by the actuation of the “#” key. The “q” is produced by actuating the “1” key twice, followed by the actuation of the “*” key. The “Z” is produced by actuating the “1” key three times, followed by the actuation of the “#” key. The “z” is produced by actuating the “1” key three times, followed by the actuation of the “*” key. The space “” is produced by actuating the “1” key four times, followed by the actuation of the “#” key.

U.S. Pat. No. 5,392,338 to Adel Danish, et al. discloses a method for entering alphabetic characters into a telephone apparatus. Danish et al. represents from left to right; the “Q” and “Z” on the “1” key. The “Q” is produced by actuating the “1” key. The “Z” is produced by actuating the “1” key twice. Numbers must be entered individually, followed by the activation of the “#” key.

U.S. Pat. No. 3,647,973 to James et al., U.S. Pat. No. 4,005,388 to Morley et al., U.S. Pat. No. 4,007,443 to Bromberg et al., U.S. Pat. No. 4,191,854 to Coles, U.S. Pat. No. 4,307,266 to Messina, U.S. Pat. No. 4,426,555 to Underkoffler, U.S. Pat. No. 4,608,457 to Fowler et al., U.S. Pat. No. 4,825,464 to Wen, are additional prior art patents where the “Q” and “Z” are represented or located on the “0” key.

U.S. Pat. No. 3,526,892 to Bartlett et al., U.S. Pat. No. 3,573,376 to Bartlett et al., U.S. Pat. No. 3,618,038 to Stein, U.S. Pat. No. 3,746,793 to Sachs, U.S. Pat. No. 3,833,765 to Hillborn et al., U.S. Pat. No. 3,870,821 to Steury, U.S. Pat. No. 3,879,722 to Knowlton, U.S. Pat. No. 3,967,273 to Knowlton, U.S. Pat. No. 4,304,968 to Klausner et al., U.S. Pat. No. 4,344,069 to Prame, U.S. Pat. No. 4,381,502 to Prame, U.S. Pat. No. 4,500,751 to Darland et al., U.S. Pat. No. 4,649,563 to Risken, U.S. Pat. No. 4,658,417 to Hashimoto et al., U.S. Pat. No. 4,677,659 to Dargan, U.S. Pat. No. 4,817,129 to Risken, U.S. Pat. No. 4,988,997 to Prame, U.S. Pat. No. 5,117,455 to Danish, U.S. Pat. No. 5,163,084 to Kim et al., U.S. Pat. No. 5,303,288 to Duffy et al., U.S. Pat. No. 5,339,358 to Danish et al., U.S. Pat. No. 5,486,823 to Tsai, U.S. Pat. No. 5,548,634 to Gahang et al., U.S. Pat. No. 5,559,512 to Jasinski et al., disclose prior art patents that use the phone keypad to enter alphanumeric data.

U.S. Pat. No. 2,073,333 to Chireix, U.S. Pat. No. 3,381,276 to James, U.S. Pat. No. 3,582,554 to LeBlang, U.S. Pat. No. 3,778,553 to Rackman, U.S. Pat. No. 4,481,508 to Kamei et al., U.S. Pat. No. 4,486,741 to Nozawa et al., U.S. Pat. No. 4,680,278 to Davis, I I et al., U.S. Pat. No. 4,724,423 to Kinoshita, U.S. Pat. No. 4,799,254 to Dayton et al., U.S. Pat. No. 4,860,234 to Lapeyre, U.S. Pat. No. 4,891,777 to Lapeyre, U.S. Pat. No. 4,910,697 to Lapeyre, U.S. Pat. No. 4,924,431 to Lapeyre, U.S. Pat. No. 4,999,795 to Lapeyre, U.S. Pat. No. 5,007,008 to Beers, U.S. Pat. No. 5,031,119 to Dulaney et al., U.S. Pat. No. 5,062,070 to Lapeyre, U.S. Pat. No. 5,067,103 to Lapeyre, U.S. Pat. No. 5,105,375 to Lapeyre, U.S. Pat. No. 5,124,940 to Lapeyre, U.S. Pat. No. 5,184,315 to Lapeyre, U.S. Pat. No. 5,274,693 to Waldman, U.S. Pat. No. 5,581,593 to Engelke et al., disclose other prior art patents.

There are also a multitude of other U.S. Patents and Patents issued in other countries that are not listed or discussed in this patent application for obvious reasons.

More than one prior art reference uses the “.QZ” on the [1] key. The control means and method of use is what differentiates the invention found in this patent application over the prior art. The presently disclosed invention requires less key actuations to produce data than all the prior art and can work on any twelve key phone keypad device to produce all QWERTY keyboard data. The invention found in this patent application is faster than Tegic T9, Motorola's iTap, Zi Corp's eZiText and all the prior art.

The fastest method of data entry into a twelve key phone device uses only eight keys, the left and right columns of four keys, found in U.S. Pat. No. 5,993,089 to Burrell, IV, entitled “8-bit Binary Code for Use as an 8-dot Braille Arrangement and Data Entry System and Method for 8-key Chordic Binary Keyboards”. The chordic data entry method reduces key activations to one chord for every data character.

One of the fastest methods of sequential and/or simultaneous data entry into a twelve key phone device is found in U.S. Pat. No. 6,043,761 to Burrell, IV, titled “Method of Using a Nine Key Alphanumeric Binary Keyboard Combined with a Three Key Keyboard Control Keyboard”, U.S. Pat. No. 6,184,803 to Burrell, IV, titled “Nine Key Alphanumeric Binary Keyboard Combined with a Three Key Keyboard Control Keyboard and Combinational Control Means” and U.S. Pat. No. 6,232,892 to Burrell, IV, titled “Method of Using a Nine Key Alphanumeric Binary Keyboard Combined with a Three Key Keyboard Control Keyboard”.

Another fastest methods of sequential and/or simultaneous data entry into a nine key device, a menu key or pointing device, is found in U.S. patent application Ser. No. 12/202,702 to Burrell, IV, titled “Nine Sensor Data Entry Keyboard and Control Means”, U.S. patent application Ser. No. 12/235,984 to Burrell, IV, titled “World's Smallest Keyboard and Control Means” and U.S. patent application Ser. No. 12/268,612 to Burrell, IV, titled “Keyboard Control Means”.

None of the prior art solutions can be used to improve the existing prior art problems associated with reducing the amount of multi-tap entries to the least amount of required taps and producing all QWERTY keyboard data. A faster multi-tap keypad and method is needed for the blind and general population. The present invention solves all the existing prior art multi-tap problems and is the fastest multi-tap method that will ever be invented.

### OBJECTS OF THE INVENTION

It is an object of the present invention to provide a twelve sensor keypad with at least three extra data characters on nine numbered sensors, for producing the fastest method of shiftable data entry.

It is another object of the present invention to provide a twelve sensor keypad with at least six extra data characters on nine numbered sensors and preferably at least three extra data characters on a tenth numbered sensor, for producing the fastest method of shiftable QWERTY character data entry.

It is still another object of the present invention to provide a shift function performed after a data character is produced in an alphabetic mode and a shiftable punctuation/symbol position mode, for producing the fastest method of data entry.

It is yet another object of the present invention to provide complete punctuation and symbols, where a space is automatically produced after a punctuation mark and the backspace function is provided for mistakes and to delete the space that is automatically produced after a punctuation mark.

It is a further object of the present invention to provide a backspace function, while in a number mode or in an alphabetic mode, using only twelve sensors.

Finally, the original object of the present invention was to provide the fastest method of multi-tap data entry, which requires less taps than all the existing prior art.

These and other objects and advantages of the present invention are provided within this patent application.

### SUMMARY OF THE INVENTION

This data entry phone invention uses a labeled twelve sensor phone keypad arrangement to produce alphanumeric data, including a space, punctuation, symbols and methods of control means. The preferred multi-tap control means makes it faster than all prior art multi-tap phone keypads and devices. The differences in the present invention, compared to the prior art are the phone keypad labeling and the system and method of producing numbers. The preferred embodiment of the present invention preferably produces twenty-six letters of an alphabet or data characters but can produce twenty-seven letters of an alphabet or data characters, such as Chinese, Japanese or some other language's alphabet, a period, a dash, a space, punctuation, symbols, character shift functions and a control means on a twelve sensor phone keypad. The preferred keypad labeling embodiments are illustrated in FIGS. 1 and 2.

Numbers are produced in the standard number mode using single sensor activations. Activating the [1] one through [9] nine sensors or the [0] zero sensor produces the sensor's numeric value. Activating the [#] pound sensor, while in the number mode, produces the backspace “BkSp” function.

Activating the [*] asterisk sensor, while in the number mode, followed by the activation of the [1] one sensor produces the “.” period (dot/decimal point). Activating the [#] pound sensor twice returns to the number mode.

Activating the [*] asterisk sensor, while in the number mode, followed by the activation of the [1] one sensor, followed by the activation of the [*] asterisk sensor produces the “-” dash (hyphen/minus sign). Activating the [#] pound sensor twice returns to the number mode.

The number mode is exited and the alphabetic mode, preferably a multi-tap data entry mode, is entered by activating the preferred [*] asterisk sensor.

Activating the preferred [#] pound sensor twice while in the alphabetic mode re-enters the number mode.

While in the alphabetic mode, activating one of the [1] one through [9] nine sensors one time produces the first left position data character, activating one of the [1] one through [9] nine sensors two times produces the second middle position data character and activating one of the [1] one through [9] nine sensors three times produces the third right position data character.

While in the alphabetic mode, after activating one of the [1] one through [9] nine sensors one, two or three times, the activation of the preferred [#] pound sensor enters the data character, allowing the next data character to be entered using the same sensor the previously entered data character was entered on. This feature increases the speed in which data can be entered into a device using the prior art preferred one second automatic entry of a data character. This feature also allows data to be entered into a device without the use of the prior art one second automatic entry of a data character.

When any type of punctuation is produced, the punctuation mark is followed by a space. Activating the preferred [*] asterisk sensor after the punctuation mark followed by a space is produced, deletes the space after the punctuation mark.

After the desired data character is produced by one of the [1] one through [9] nine sensors, activation of a preferable first left sensor, preferably the [*] asterisk labeled sensor, of a second set of three sensors, produces the shift function and produces an upper-case data character or a secondary data character.

After the desired data character is produced by one of the [1] one through [9] nine sensors, activation of a preferable first left sensor, preferably the [*] asterisk labeled sensor, of a second set of three sensors, twice produces the backspace function.

While in the alphabetic mode, activating the [0] zero sensor produces a “ ” space.

While in the alphabetic mode, activating the [0] zero sensor twice produces a Tab function or Enter function.

Activating the preferred [#] pound sensor followed by the preferred [*] asterisk sensor enters a punctuation/symbol mode. Activating one of the [1] one through [9] nine sensors or the [0] sensor, while in the punctuation/symbol mode produces a first left data character (punctuation mark or symbol), activating the preferred [*] asterisk sensor followed by the activation of one of the [1] one through [9] nine sensors or the [0] sensor, while in the punctuation/symbol mode produces a second middle data character (punctuation mark or symbol), activating the preferred [*] asterisk sensor followed by the activation of one of the [1] one through [9] nine sensors or the [0] sensor, while in the punctuation/symbol mode produces a third right data character (punctuation mark or symbol), activating the preferred [*] asterisk sensor followed by the activation of one of the [1] one through [9] nine sensors or the [0] sensor, while in the punctuation/symbol mode produces a first left data character (punctuation mark or symbol), etc.

The alphabetic mode is automatically re-entered into after the punctuation mark or symbol is produced. The user must activate the preferred [#] pound sensor followed by the preferred [*] asterisk sensor to re-enter the punctuation/symbol mode.

Alternatively, simultaneously activating the preferred [#] pound sensor and the preferred [*] asterisk sensor enters a punctuation/symbol mode. The alphabetic mode is re-entered into after the punctuation mark or symbol is produced. The user must simultaneously activate the preferred [#] pound sensor and the preferred [*] asterisk sensor to re-enter the punctuation/symbol mode.

When a punctuation mark is produced, the punctuation mark is followed by a space. Activating the preferred [*] asterisk sensor after the punctuation mark/space is produced, deletes the space after the punctuation mark. Activating the preferred [0] zero sensor after a period/space is produced, deletes the space after the period.

The present invention provides the fastest method of multi-tap data entry using a twelve sensor phone keypad. The present invention also provides the fastest method of data entry using simultaneous key activations using a twelve sensor phone keypad. This and other objects and advantages of the present invention are provided within this patent application. The present invention also provides an improved keypad labeling.

These and other objects, features and advantages of the present invention will be better understood in connection with the following drawings and descriptions of the preferred embodiments.

### DESCRIPTION OF THE DRAWINGS

For a better understanding of the invention as well as other objects, features and advantages thereof, reference is made to the following detailed description to be read in conjunction with the accompanying drawings, wherein:

FIG. 1 shows a preferred embodiment for a labeled twelve sensor keypad, with a period and twenty-six letters of an alphabet on nine sensors.

FIG. 2 shows the preferred embodiment of FIG. 1 with a period and twenty-six letters of an alphabet on nine sensors and three punctuation marks or symbols on ten sensors.

FIG. 3 shows the preferred display screen embodiment of FIG. 1 while in a number mode.

FIG. 4 shows the preferred display screen embodiment of FIG. 1 while in an alphabetic mode.

FIG. 5 shows one preferred display screen embodiment of FIG. 1 while in a punctuation mode.

FIG. 6 shows one preferred display screen embodiment of FIG. 1 while in a first punctuation mode.

FIG. 7 shows one preferred display screen embodiment of FIG. 1 while in a second punctuation mode.

FIG. 8 shows one preferred display screen embodiment of FIG. 1 while in a third punctuation mode.

FIG. 9a shows a chart showing with the amount of key actuations required to produce the Guinness Book of World Records 160 character phrase “The razor-toothed piranhas of the genera Serrasalmus and Pygocentrus are the most ferocious freshwater fish in the world. In reality they seldom attack a human.”, using the multi-tap keyboard data entry method found in the present patent application disclosure.

FIG. 9b shows a chart showing with the amount of key actuations required to produce the Guinness Book of World Records 160 character phrase “The razor-toothed piranhas of the genera Serrasalmus and Pygocentrus are the most ferocious freshwater fish in the world. In reality they seldom attack a human.”, using the simultaneous keyboard data entry method found in the present patent application disclosure.

### LIST OF REFERENCE NUMBERING AND LABELING

1 labels a first sensor.

2 labels a second sensor.

3 labels a third sensor.

4 labels a fourth sensor.

5 labels a fifth sensor.

6 labels a sixth sensor.

7 labels a seventh sensor.

8 labels an eighth sensor.

9 labels a ninth sensor.

0 labels a zero sensor or a tenth sensor.

* labels an asterisk sensor or an eleventh sensor.

# labels a pound sensor or a twelfth sensor.

### DETAILED DESCRIPTION OF THE PREFERRED EMBODIMENT

In order to more fully understand the invention, during the course of this description, the fastest multi-tap phone invention and preferred embodiments, will be labeled and explained to easily identify like elements according to the different embodiments which illustrate the invention. In the description and in the claims language, the sensors [1] one through [9] nine will be also referred to as first through ninth sensors, the [0] sensor will also be referred to as a tenth sensor, the [*] asterisk sensor will also be referred to as an eleventh sensor and the [#] pound sensor will also be referred to as a twelfth sensor.

The invention disclosed in the present patent application describing a data entry phone invention uses a labeled twelve sensor phone keypad arrangement to produce alphanumeric data, including a space, punctuation, symbols and multiple methods of control means. The preferred multi-tap control means makes it faster than all prior art multi-tap phone keypads and devices. The differences in the present invention, compared to the prior art, are the phone keypad labeling and the system and method of producing data. The preferred embodiment of the present invention preferably produces twenty-six letters of an alphabet or data characters but can produce twenty-seven letters of an alphabet or data characters, such as Chinese, Japanese or some other language's alphabet, a period, a dash, a space, punctuation, symbols, character shift functions and a control means on a twelve sensor phone keypad.

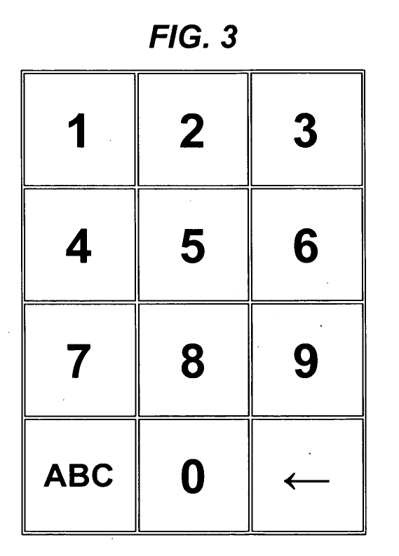

Referring to the preferred keypad labeling embodiment for a refreshable display device illustrated in FIG. 3, numbers are produced in the standard number mode using single sensor activations. Activating the [1] one through [9] nine sensors or the [0] zero sensor produces the sensor's numeric value. Activating the preferred [#] pound sensor once, while in the number mode, produces the backspace “BkSp” function.

Activating the preferred [*] asterisk sensor, while in the number mode, followed by the activation of the [1] one sensor produces the “.” period (dot/decimal point). Activating the preferred [#] pound sensor twice returns to the number mode.

Activating the preferred [*] asterisk sensor, while in the number mode, followed by the activation of the [1] one sensor combined with the activation of the preferred [*] asterisk sensor produces the “-” dash (hyphen/minus sign). Activating the preferred [#] pound sensor twice returns to the number mode. Simultaneously activating the [1] one sensor and the preferred [*] asterisk sensor reduces the two sequential sensor activations to one simultaneous two sensor activation.

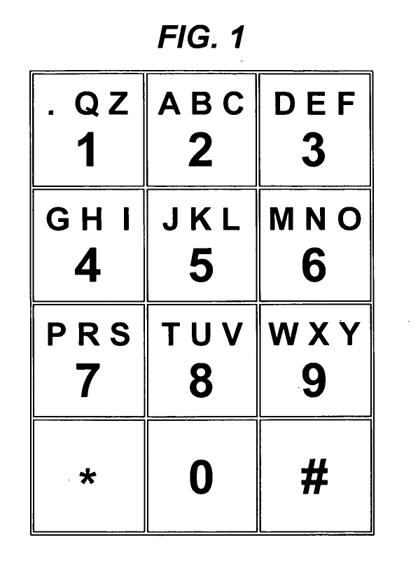

Referring to the preferred keypad labeling embodiment illustrated in FIG. 1, the preferred keypad labeling embodiment, has the characters “.QZ” (period, Q and Z) on the preferred number “1” sensor, the “ABC” on the preferred “2” sensor, the “DEF” on the preferred “3” sensor, the “GHI” on the preferred “4” sensor, the “JKL” on the preferred “5” sensor, the “MNO” on the preferred “6” sensor, the “PRS” on the preferred “7” sensor, the “TUV” on the preferred “8” sensor and the “WXY” on the “9” sensor. The preferred three data character sensor labeling is preferably the previously described embodiment, but the nine numbered sensors can be labeled in any arrangement or can be labeled with any three or more characters on any one of the nine sensors, as long as at least twenty-seven data characters are produced on the [1] one through [9] nine sensors while in an alphabetic multi-tap mode, a sequential alphabetic mode or in a simultaneous alphabetic mode. Simultaneously activating two sensors reduces the two sequential sensor activations to one simultaneous two sensor activation.

The number mode is exited and the alphabetic mode is entered, preferably a multi-tap data entry mode, by activating the preferred [*] asterisk sensor at least once.

Activating the preferred [#] pound sensor twice while in the alphabetic mode re-enters the number mode.

While in the alphabetic mode, activating one of the [1] one through [9] nine sensors one time produces the first left position data character, activating one of the [1] one through [9] nine sensors two times produces the second middle position data character and activating one of the [1] one through [9] nine sensors three times produces the third right position data character.

In one preferred embodiment, where all lower-case letters are produced, activating the preferred [1] one sensor one time produces the “.” period followed by a space, activating the preferred [1] one sensor two times produces the “q” and activating the preferred [1] one sensor three times produces the “z”.

When the period is produced, it is preferably followed by a space. Activating the [0] zero sensor after the period followed by a space is produced, deletes the space after the punctuation mark.

When any type of punctuation is produced, it is preferably followed by a space. Activating the preferred [*] asterisk sensor after the punctuation mark followed by a space is produced, deletes the space after the punctuation mark.

Activating the preferred [2] two sensor one time produces the “a”, activating the preferred [2] two sensor two times produces the “b” and activating the preferred [2] two sensor three times produces the “c”.

Activating the preferred [3] three sensor one time produces the “d”, activating the preferred [3] three sensor two times produces the “e” and activating the preferred [3] three sensor three times produces the “f”.

Activating the preferred [4] four sensor one time produces the “g”, activating the preferred [4] four sensor two times produces the “h” and activating the preferred [4] four sensor three times produces the “i”.

Activating the preferred [5] five sensor one time produces the “j”, activating the preferred [5] five sensor two times produces the “k” and activating the preferred [5] five sensor three times produces the “l”.

Activating the preferred [6] sensor one time produces the “m”, activating the preferred [6] sensor two times produces the “n” and activating the preferred [6] sensor three times produces the “o”.

Activating the preferred [7] seven sensor one time produces the “p”, activating the preferred [7] seven sensor two times produces the “r” and activating the preferred [7] seven sensor three times produces the “s”.

Activating the preferred [8] eight sensor one time produces the “t”, activating the preferred [8] eight sensor two times produces the “u” and activating the preferred [8] eight sensor three times produces the “v”.

Activating the preferred [9] nine sensor one time produces the “w”, activating the preferred [9] nine sensor two times produces the “x” and activating the preferred [9] nine sensor three times produces the “y”.

While in the alphabetic mode, after activating one of the [1] one through [9] nine sensors one, two or three times, the activation of the preferred [#] pound sensor enters the data character, allowing the next data character to be entered using the same sensor the previously entered data character was entered on. This feature increases the speed in which data can be entered into a device using the prior art preferred one second automatic entry of a data character. This feature also allows data to be entered into a device without the use of the prior art one second automatic entry of a data character.

In another preferred embodiment, where all capital letters are produced, activating the preferred [1] one sensor one time produces the “.” period followed by a space, activating the preferred [1] one sensor two times produces the “Q” and activating the preferred [1] one sensor three times produces the “Z”.

When the period is produced, it is preferably followed by a space. Activating the [0] zero sensor after the period followed by a space is produced, deletes the space after the punctuation mark.

Activating the preferred [2] two sensor one time produces the “A”, activating the preferred [2] two sensor two times produces the “B” and activating the preferred [2] two sensor three times produces the “C”.

Activating the preferred [3] three sensor one time produces the “D”, activating the preferred [3] three sensor two times produces the “E” and activating the preferred [3] three sensor three times produces the “F”.

Activating the preferred [4] four sensor one time produces the “G”, activating the preferred [4] four sensor two times produces the “H” and activating the preferred [4] four sensor three times produces the “I”.

Activating the preferred [5] five sensor one time produces the “J”, activating the preferred [5] five sensor two times produces the “K” and activating the preferred [5] five sensor three times produces the “L”.

Activating the preferred [6] sensor one time produces the “M”, activating the preferred [6] sensor two times produces the “N” and activating the preferred [6] sensor three times produces the “O”.

Activating the preferred [7] seven sensor one time produces the “P”, activating the preferred [7] seven sensor two times produces the “R” and activating the preferred [7] seven sensor three times produces the “S”.

Activating the preferred [8] eight sensor one time produces the “T”, activating the preferred [8] eight sensor two times produces the “U” and activating the preferred [8] eight sensor three times produces the “V”.

Activating the preferred [9] nine sensor one time produces the “W”, activating the preferred [9] nine sensor two times produces the “X” and activating the preferred [9] nine sensor three times produces the “Y”.

After the desired data character is produced in a multi-tap mode by one of the [1] one through [9] nine sensors, activation of a preferable first left sensor, preferably the labeled [*] asterisk labeled sensor twice produces the backspace function.

While in the alphabetic mode, after activating one of the [1] one through [9] nine sensors one, two or three times, the activation of the preferred [#] pound sensor enters the data character, allowing the next data character to be entered using the same sensor the previously entered data character was entered on. This feature increases the speed in which data can be entered into a device using the prior art preferred one second automatic entry of a data character. This feature also allows data to be entered into a device without the use of the prior art one second automatic entry of a data character.

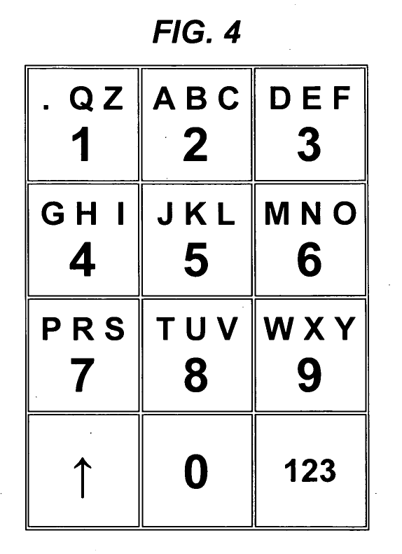

Referring to the preferred keypad labeling embodiment for a refreshable display device illustrated in FIG. 4, after the desired data character is produced by one of the [1] one through [9] nine sensors, while in an alphabetic multi-tap mode, activation of a preferable first left sensor, preferably the [*] asterisk labeled sensor, produces the shift function and produces an upper-case data character or a data character from a second data character set.

Activating the preferred [1] one sensor one time produces the “.” period followed by a space, activating the preferred [1] one sensor one time followed by the preferred [*] asterisk sensor produces the “-” dash, activating the preferred [1] one sensor two times followed by the preferred [*] asterisk sensor produces the “Q” and activating the preferred [1] one sensor three times followed by the preferred [*] asterisk sensor produces the “Z”.

Activating the preferred [2] two sensor one time followed by the preferred [*] asterisk sensor produces the “A”, activating the preferred [2] two sensor two times followed by the preferred [*] asterisk sensor produces the “B” and activating the preferred [2] two sensor three times followed by the preferred [*] asterisk sensor produces the “C”.

Activating the preferred [3] three sensor one time followed by the preferred [*] asterisk sensor produces the “D”, activating the preferred [3] three sensor two times followed by the preferred [*] asterisk sensor produces the “E” and activating the preferred [3] three sensor three times followed by the preferred [*] asterisk sensor produces the “F”.

Activating the preferred [4] four sensor one time followed by the preferred [*] asterisk sensor produces the “G”, activating the preferred [4] four sensor two times followed by the preferred [*] asterisk sensor produces the “H” and activating the preferred [4] four sensor three times followed by the preferred [*] asterisk sensor produces the “I”.

Activating the preferred [5] five sensor one time followed by the preferred [*] asterisk sensor produces the “J”, activating the preferred [5] five sensor two times followed by the preferred [*] asterisk sensor produces the “K” and activating the preferred [5] five sensor three times followed by the preferred [*] asterisk sensor produces the “L”.

Activating the preferred [6] sensor one time followed by the preferred [*] asterisk sensor produces the “M”, activating the preferred [6] sensor two times followed by the preferred [*] asterisk sensor produces the “N” and activating the preferred [6] sensor three times followed by the preferred [*] asterisk sensor produces the “O”.

Activating the preferred [7] seven sensor one time followed by the preferred [*] asterisk sensor produces the “P”, activating the preferred [7] seven sensor two times followed by the preferred [*] asterisk sensor produces the “R” and activating the preferred [7] seven sensor three times followed by the preferred [*] asterisk sensor produces the “S”.

Activating the preferred [8] eight sensor one time followed by the preferred [*] asterisk sensor produces the “T”, activating the preferred [8] eight sensor two times followed by the preferred [*] asterisk sensor produces the “U” and activating the preferred [8] eight sensor three times followed by the preferred [*] asterisk sensor produces the “V”.

Activating the preferred [9] nine sensor one time followed by the preferred [*] asterisk sensor produces the “W”, activating the preferred [9] nine sensor two times followed by the preferred [*] asterisk sensor produces the “X” and activating the preferred [9] nine sensor three times followed by the preferred [*] asterisk sensor produces the “Y”.

After the desired data character is produced in a multi-tap mode by one of the [1] one through [9] nine sensors, activation of a preferable first left sensor, preferably the labeled [*] asterisk labeled sensor twice produces the backspace function.

In an another embodiment, simultaneously activating two sensors reduces the one, two or three sequential sensor activations to one simultaneous two sensor activation. While in a simultaneous two key data entry alphabetic mode embodiment, activating one of the [1] one through [9] nine sensors simultaneously with the preferred [*] asterisk sensor produces the first left position data character, activating one of the [1] one through [9] nine sensors simultaneously with the [0] zero sensor produces the second middle position data character and activating one of the [1] one through [9] nine sensors simultaneously with the preferred [#] pound sensor produces the third right position data character.

Activating the preferred [1] one sensor one time produces the “.” period followed by a space, activating the preferred [1] one sensor simultaneously with the preferred [*] asterisk sensor produces the “-” dash, activating the preferred [1] one sensor simultaneously with the [0] zero sensor produces the “q” and activating the preferred [1] one sensor simultaneously with the preferred [#] pound sensor produces the “z”.

When the period is produced, it is preferably followed by a space. Activating the [0] zero sensor after the period followed by a space is produced, deletes the space after the punctuation mark.

Activating the preferred [2] two sensor simultaneously with the preferred [*] asterisk sensor produces the “a”, activating the preferred [2] two sensor simultaneously with the [0] zero sensor produces the “b” and activating the preferred [2] two sensor simultaneously with the preferred [#] pound sensor produces the “c”.

Activating the preferred [3] three sensor simultaneously with the preferred [*] asterisk sensor produces the “d”, activating the preferred [3] three sensor simultaneously with the [0] zero sensor produces the “e” and activating the preferred [3] three sensor simultaneously with the preferred [#] pound sensor produces the “f”.

Activating the preferred [4] four sensor simultaneously with the preferred [*] asterisk sensor produces the “g”, activating the preferred [4] four sensor simultaneously with the [0] zero sensor produces the “h” and activating the preferred [4] four sensor simultaneously with the preferred [#] pound sensor produces the “i”.

Activating the preferred [5] five sensor simultaneously with the preferred [*] asterisk sensor produces the “j”, activating the preferred [5] five sensor simultaneously with the [0] zero sensor produces the “k” and activating the preferred [5] five sensor simultaneously with the preferred [#] pound sensor produces the “l”.

Activating the preferred [6] sensor simultaneously with the preferred [*] asterisk sensor produces the “m”, activating the preferred [6] sensor simultaneously with the [0] zero sensor produces the “n” and activating the preferred [6] sensor simultaneously with the preferred [#] pound sensor produces the “o”.

Activating the preferred [7] seven sensor simultaneously with the preferred [*] asterisk sensor produces the “p”, activating the preferred [7] seven sensor simultaneously with the [0] zero sensor produces the “r” and activating the preferred [7] seven sensor simultaneously with the preferred [#] pound sensor produces the “s”.

Activating the preferred [8] eight sensor simultaneously with the preferred [*] asterisk sensor produces the “t”, activating the preferred [8] eight sensor simultaneously with the [0] zero sensor produces the “u” and activating the preferred [8] eight sensor simultaneously with the preferred [#] pound sensor produces the “v”.

Activating the preferred [9] nine sensor simultaneously with the preferred [*] asterisk sensor produces the “w”, activating the preferred [9] nine sensor simultaneously with the [0] zero sensor produces the “x” and activating the preferred [9] nine sensor simultaneously with the preferred [#] pound sensor produces the “y”.

Alternatively, simultaneous activation of any two sensors can be used to exit the number mode and enter the alphabet mode.

In a shiftable simultaneous two key activation embodiment, activating one of the [1] one through [9] nine sensors simultaneously with the preferred [*] asterisk sensor produces the first left position data character followed by the activation of the preferred [*] asterisk sensor produces an upper-case data character or a data character from a second set of data characters, activating one of the [1] one through [9] nine sensors simultaneously with the [0] zero sensor produces the second middle position data character followed by the activation of the preferred [*] asterisk sensor produces an upper-case data character or a data character from a second set of data characters and activating one of the [1] one through [9] nine sensors simultaneously with the preferred [#] pound sensor produces the third right position data character followed by the activation of the preferred [*] asterisk sensor produces an upper-case data character or a data character from a second set of data characters.

Activating the preferred [1] one sensor one time produces the “.” period followed by a space. Activating the preferred [1] one sensor simultaneously with the preferred [*] asterisk sensor produces the “-” dash.

Activating the preferred [1] one sensor simultaneously with the [0] zero sensor produces the “q”, when followed by the activation of the preferred [*] asterisk sensor produces the “Q”.

Activating the preferred [1] one sensor simultaneously with the preferred [#] pound sensor produces the “z”, when followed by the activation of the preferred [*] asterisk sensor produces the “Z”.

Activating the preferred [2] two sensor simultaneously with the preferred [*] asterisk sensor produces the “a”, when followed by the activation of the preferred [*] asterisk sensor produces the “A”.

Activating the preferred [2] two sensor simultaneously with the [0] zero sensor produces the “b”, when followed by the activation of the preferred [*] asterisk sensor produces the “B”.

Activating the preferred [2] two sensor simultaneously with the preferred [#] pound sensor produces the “c”, when followed by the activation of the preferred [*] asterisk sensor produces the “C”.

Activating the preferred [3] three sensor simultaneously with the preferred [*] asterisk sensor produces the “d”, when followed by the activation of the preferred [*] asterisk sensor produces the “D”.

Activating the preferred [3] three sensor simultaneously with the [0] zero sensor produces the “e”, when followed by the activation of the preferred [*] asterisk sensor produces the “E”.

Activating the preferred [3] three sensor simultaneously with the preferred [#] pound sensor produces the “f”, when followed by the activation of the preferred [*] asterisk sensor produces the “F”.

Activating the preferred [4] four sensor simultaneously with the preferred [*] asterisk sensor produces the “g”, when followed by the activation of the preferred [*] asterisk sensor produces the “G”.

Activating the preferred [4] four sensor simultaneously with the [0] zero sensor produces the “h”, when followed by the activation of the preferred [*] asterisk sensor produces the “H”.

Activating the preferred [4] four sensor simultaneously with the preferred [#] pound sensor produces the “i”, when followed by the activation of the preferred [*] asterisk sensor produces the “I”.

Activating the preferred [5] five sensor simultaneously with the preferred [*] asterisk sensor produces the “j”, when followed by the activation of the preferred [*] asterisk sensor produces the “J”.

Activating the preferred [5] five sensor simultaneously with the [0] zero sensor produces the “k”, when followed by the activation of the preferred [*] asterisk sensor produces the “K”.

Activating the preferred [5] five sensor simultaneously with the preferred [#] pound sensor produces the “l”, when followed by the activation of the preferred [*] asterisk sensor produces the “L”.

Activating the preferred [6] sensor simultaneously with the preferred [*] asterisk sensor produces the “m”, when followed by the activation of the preferred [*] asterisk sensor produces the “M”.

Activating the preferred [6] sensor simultaneously with the [0] zero sensor produces the “n”, when followed by the activation of the preferred [*] asterisk sensor produces the “N”.

Activating the preferred [6] sensor simultaneously with the preferred [#] pound sensor produces the “o”, when followed by the activation of the preferred [*] asterisk sensor produces the “O”.

Activating the preferred [7] seven sensor simultaneously with the preferred [*] asterisk sensor produces the “p”, when followed by the activation of the preferred [*] asterisk sensor produces the “P”.

Activating the preferred [7] seven sensor simultaneously with the [0] zero sensor produces the “r”, when followed by the activation of the preferred [*] asterisk sensor produces the “R”.

Activating the preferred [7] seven sensor simultaneously with the preferred [#] pound sensor produces the “s”, when followed by the activation of the preferred [*] asterisk sensor produces the “S”.

Activating the preferred [8] eight sensor simultaneously with the preferred [*] asterisk sensor produces the “t”, when followed by the activation of the preferred [*] asterisk sensor produces the “T”.

Activating the preferred [8] eight sensor simultaneously with the [0] zero sensor produces the “u”, when followed by the activation of the preferred [*] asterisk sensor produces the “U”.

Activating the preferred [8] eight sensor simultaneously with the preferred [#] pound sensor produces the “v”, when followed by the activation of the preferred [*] asterisk sensor produces the “V”.

Activating the preferred [9] nine sensor simultaneously with the preferred [*] asterisk sensor produces the “w”, when followed by the activation of the preferred [*] asterisk sensor produces the “W”.

Activating the preferred [9] nine sensor simultaneously with the [0] zero sensor produces the “x”, when followed by the activation of the preferred [*] asterisk sensor produces the “X”.

Activating the preferred [9] nine sensor simultaneously with the preferred [#] pound sensor produces the “y”, when followed by the activation of the preferred [*] asterisk sensor produces the “Y”. Activating the preferred [*] asterisk sensor twice produces the backspace function.

In one alternative embodiment of a shiftable simultaneous two key activation data entry method, activating one of the [1] one through [9] nine sensors produces the first left position data character followed by the activation of the preferred [*] asterisk sensor produces an upper-case data character or a data character from a second set of data characters, activating one of the [1] one through [9] nine sensors simultaneously with the [0] zero sensor produces the second middle position data character followed by the activation of the preferred [*] asterisk sensor produces an upper-case data character or a data character from a second set of data characters and activating one of the [1] one through [9] nine sensors simultaneously with the preferred [#] pound sensor produces the third right position data character followed by the activation of the preferred [*] asterisk sensor produces an upper-case data character or a data character from a second set of data characters.

Activating the preferred [1] one sensor one time produces the “.” period followed by a space. Activating the preferred [1] one sensor simultaneously with the preferred [*] asterisk sensor produces the “-” dash.

Activating the preferred [1] one sensor simultaneously with the [0] zero sensor produces the “q”, when followed by the activation of the preferred [*] asterisk sensor produces the “Q”.

Activating the preferred [1] one sensor simultaneously with the preferred [#] pound sensor produces the “z”, when followed by the activation of the preferred [*] asterisk sensor produces the “Z”.

Activating the preferred [2] two sensor produces the “a”, when followed by the activation of the preferred [*] asterisk sensor produces the “A”.

Activating the preferred [2] two sensor simultaneously with the [0] zero sensor produces the “b”, when followed by the activation of the preferred [*] asterisk sensor produces the “B”.

Activating the preferred [2] two sensor simultaneously with the preferred [#] pound sensor produces the “c”, when followed by the activation of the preferred [*] asterisk sensor produces the “C”.

Activating the preferred [3] three sensor produces the “d”, when followed by the activation of the preferred [*] asterisk sensor produces the “D”.

Activating the preferred [3] three sensor simultaneously with the [0] zero sensor produces the “e”, when followed by the activation of the preferred [*] asterisk sensor produces the “E”.

Activating the preferred [3] three sensor simultaneously with the preferred [#] pound sensor produces the “f”, when followed by the activation of the preferred [*] asterisk sensor produces the “F”.

Activating the preferred [4] four sensor produces the “g”, when followed by the activation of the preferred [*] asterisk sensor produces the “G”.

Activating the preferred [4] four sensor simultaneously with the [0] zero sensor produces the “h”, when followed by the activation of the preferred [*] asterisk sensor produces the “H”.

Activating the preferred [4] four sensor simultaneously with the preferred [#] pound sensor produces the “i”, when followed by the activation of the preferred [*] asterisk sensor produces the “I”.

Activating the preferred [5] five sensor produces the “j”, when followed by the activation of the preferred [*] asterisk sensor produces the “J”.

Activating the preferred [5] five sensor simultaneously with the [0] zero sensor produces the “k”, when followed by the activation of the preferred [*] asterisk sensor produces the “K”.

Activating the preferred [5] five sensor simultaneously with the preferred [#] pound sensor produces the “l”, when followed by the activation of the preferred [*] asterisk sensor produces the “L”.

Activating the preferred [6] sensor produces the “m”, when followed by the activation of the preferred [*] asterisk sensor produces the “M”.

Activating the preferred [6] sensor simultaneously with the [0] zero sensor produces the “n”, when followed by the activation of the preferred [*] asterisk sensor produces the “N”.

Activating the preferred [6] sensor simultaneously with the preferred [#] pound sensor produces the “o”, when followed by the activation of the preferred [*] asterisk sensor produces the “O”.

Activating the preferred [7] seven sensor produces the “p”, when followed by the activation of the preferred [*] asterisk sensor produces the “P”.

Activating the preferred [7] seven sensor simultaneously with the [0] zero sensor produces the “r”, when followed by the activation of the preferred [*] asterisk sensor produces the “R”.

Activating the preferred [7] seven sensor simultaneously with the preferred [#] pound sensor produces the “s”, when followed by the activation of the preferred [*] asterisk sensor produces the “S”.

Activating the preferred [8] eight sensor produces the “t”, when followed by the activation of the preferred [*] asterisk sensor produces the “T”.

Activating the preferred [8] eight sensor simultaneously with the [0] zero sensor produces the “u”, when followed by the activation of the preferred [*] asterisk sensor produces the “U”.

Activating the preferred [8] eight sensor simultaneously with the preferred [#] pound sensor produces the “v”, when followed by the activation of the preferred [*] asterisk sensor produces the “V”.

Activating the preferred [9] nine sensor produces the “w”, when followed by the activation of the preferred [*] asterisk sensor produces the “W”.

Activating the preferred [9] nine sensor simultaneously with the [0] zero sensor produces the “x”, when followed by the activation of the preferred [*] asterisk sensor produces the “X”.

Activating the preferred [9] nine sensor simultaneously with the preferred [#] pound sensor produces the “y”, when followed by the activation of the preferred [*] asterisk sensor produces the “Y”. Activating the preferred [*] asterisk sensor twice produces the backspace function.

In another alternative embodiment of a shiftable simultaneous two key activation data entry method, activating one of the [1] one through [9] nine sensors simultaneously with the preferred [*] asterisk sensor produces the first left position data character followed by the activation of the preferred [*] asterisk sensor produces an upper-case data character or a data character from a second set of data characters, activating one of the [1] one through [9] nine sensors produces the second middle position data character followed by the activation of the preferred [*] asterisk sensor produces an upper-case data character or a data character from a second set of data characters and activating one of the [1] one through [9] nine sensors simultaneously with the preferred [#] pound sensor produces the third right position data character followed by the activation of the preferred [*] asterisk sensor produces an upper-case data character or a data character from a second set of data characters.

Activating the preferred [1] one sensor one time produces the “.” period followed by a space. Activating the preferred [1] one sensor simultaneously with the preferred [*] asterisk sensor produces the “-” dash.

Activating the preferred [1] one sensor produces the “q”, when followed by the activation of the preferred [*] asterisk sensor produces the “Q”.

Activating the preferred [1] one sensor simultaneously with the preferred [#] pound sensor produces the “z”, when followed by the activation of the preferred [*] asterisk sensor produces the “Z”.

Activating the preferred [2] two sensor simultaneously with the preferred [*] asterisk sensor produces the “a”, when followed by the activation of the preferred [*] asterisk sensor produces the “A”.

Activating the preferred [2] two sensor produces the “b”, when followed by the activation of the preferred [*] asterisk sensor produces the “B”.

Activating the preferred [2] two sensor simultaneously with the preferred [#] pound sensor produces the “c”, when followed by the activation of the preferred [*] asterisk sensor produces the “C”.

Activating the preferred [3] three sensor simultaneously with the preferred [*] asterisk sensor produces the “d”, when followed by the activation of the preferred [*] asterisk sensor produces the “D”.

Activating the preferred [3] three sensor produces the “e”, when followed by the activation of the preferred [*] asterisk sensor produces the “E”.

Activating the preferred [3] three sensor simultaneously with the preferred [#] pound sensor produces the “f”, when followed by the activation of the preferred [*] asterisk sensor produces the “F”.

Activating the preferred [4] four sensor simultaneously with the preferred [*] asterisk sensor produces the “g”, when followed by the activation of the preferred [*] asterisk sensor produces the “G”.

Activating the preferred [4] four sensor produces the “h”, when followed by the activation of the preferred [*] asterisk sensor produces the “H”.

Activating the preferred [4] four sensor simultaneously with the preferred [#] pound sensor produces the “i”, when followed by the activation of the preferred [*] asterisk sensor produces the “I”.

Activating the preferred [5] five sensor simultaneously with the preferred [*] asterisk sensor produces the “j”, when followed by the activation of the preferred [*] asterisk sensor produces the “J”.

Activating the preferred [5] five sensor produces the “k”, when followed by the activation of the preferred [*] asterisk sensor produces the “K”.

Activating the preferred [5] five sensor simultaneously with the preferred [#] pound sensor produces the “l”, when followed by the activation of the preferred [*] asterisk sensor produces the “L”.

Activating the preferred [6] sensor simultaneously with the preferred [*] asterisk sensor produces the “m”, when followed by the activation of the preferred [*] asterisk sensor produces the “M”.

Activating the preferred [6] sensor produces the “n”, when followed by the activation of the preferred [*] asterisk sensor produces the “N”.

Activating the preferred [6] sensor simultaneously with the preferred [#] pound sensor produces the “o”, when followed by the activation of the preferred [*] asterisk sensor produces the “O”.

Activating the preferred [7] seven sensor simultaneously with the preferred [*] asterisk sensor produces the “p”, when followed by the activation of the preferred [*] asterisk sensor produces the “P”.

Activating the preferred [7] seven sensor produces the “r”, when followed by the activation of the preferred [*] asterisk sensor produces the “R”.

Activating the preferred [7] seven sensor simultaneously with the preferred [#] pound sensor produces the “s”, when followed by the activation of the preferred [*] asterisk sensor produces the “S”.

Activating the preferred [8] eight sensor simultaneously with the preferred [*] asterisk sensor produces the “t”, when followed by the activation of the preferred [*] asterisk sensor produces the “T”.

Activating the preferred [8] eight sensor produces the “u”, when followed by the activation of the preferred [*] asterisk sensor produces the “U”.

Activating the preferred [8] eight sensor simultaneously with the preferred [#] pound sensor produces the “v”, when followed by the activation of the preferred [*] asterisk sensor produces the “V”.

Activating the preferred [9] nine sensor simultaneously with the preferred [*] asterisk sensor produces the “w”, when followed by the activation of the preferred [*] asterisk sensor produces the “W”.

Activating the preferred [9] nine sensor produces the “x”, when followed by the activation of the preferred [*] asterisk sensor produces the “X”.

Activating the preferred [9] nine sensor simultaneously with the preferred [#] pound sensor produces the “y”, when followed by the activation of the preferred [*] asterisk sensor produces the “Y”. Activating the preferred [*] asterisk sensor twice produces the backspace function.

In another alternative embodiment of a shiftable simultaneous two key activation data entry method, activating one of the [1] one through [9] nine sensors simultaneously with the preferred [*] asterisk sensor produces the first left position data character followed by the activation of the preferred [*] asterisk sensor produces an upper-case data character or a data character from a second set of data characters, activating one of the [1] one through [9] nine sensors simultaneously with the [0] zero sensor produces the second middle position data character followed by the activation of the preferred [*] asterisk sensor produces an upper-case data character or a data character from a second set of data characters and activating one of the [1] one through [9] nine sensors produces the third right position data character followed by the activation of the preferred [*] asterisk sensor produces an upper-case data character or a data character from a second set of data characters.

Activating the preferred [1] one sensor one time produces the “.” period followed by a space. Activating the preferred [1] one sensor simultaneously with the preferred [*] asterisk sensor produces the “-” dash.

Activating the preferred [1] one sensor simultaneously with the [0] zero sensor produces the “q”, when followed by the activation of the preferred [*] asterisk sensor produces the “Q”.

Activating the preferred [1] one sensor produces the “z”, when followed by the activation of the preferred [*] asterisk sensor produces the “Z”.

Activating the preferred [2] two sensor simultaneously with the preferred [*] asterisk sensor produces the “a”, when followed by the activation of the preferred [*] asterisk sensor produces the “A”.

Activating the preferred [2] two sensor simultaneously with the [0] zero sensor produces the “b”, when followed by the activation of the preferred [*] asterisk sensor produces the “B”.

Activating the preferred [2] two sensor produces the “c”, when followed by the activation of the preferred [*] asterisk sensor produces the “C”.

Activating the preferred [3] three sensor simultaneously with the preferred [*] asterisk sensor produces the “d”, when followed by the activation of the preferred [*] asterisk sensor produces the “D”.

Activating the preferred [3] three sensor simultaneously with the [0] zero sensor produces the “e”, when followed by the activation of the preferred [*] asterisk sensor produces the “E”.

Activating the preferred [3] three sensor produces the “f”, when followed by the activation of the preferred [*] asterisk sensor produces the “F”.

Activating the preferred [4] four sensor simultaneously with the preferred [*] asterisk sensor produces the “g”, when followed by the activation of the preferred [*] asterisk sensor produces the “G”.

Activating the preferred [4] four sensor simultaneously with the [0] zero sensor produces the “h”, when followed by the activation of the preferred [*] asterisk sensor produces the “H”.

Activating the preferred [4] four sensor produces the “i”, when followed by the activation of the preferred [*] asterisk sensor produces the “I”.

Activating the preferred [5] five sensor simultaneously with the preferred [*] asterisk sensor produces the “j”, when followed by the activation of the preferred [*] asterisk sensor produces the “J”.

Activating the preferred [5] five sensor simultaneously with the [0] zero sensor produces the “k”, when followed by the activation of the preferred [*] asterisk sensor produces the “K”.

Activating the preferred [5] five sensor produces the “l”, when followed by the activation of the preferred [*] asterisk sensor produces the “L”.

Activating the preferred [6] sensor simultaneously with the preferred [*] asterisk sensor produces the “m”, when followed by the activation of the preferred [*] asterisk sensor produces the “M”.

Activating the preferred [6] sensor simultaneously with the [0] zero sensor produces the “n”, when followed by the activation of the preferred [*] asterisk sensor produces the “N”.

Activating the preferred [6] sensor produces the “o”, when followed by the activation of the preferred [*] asterisk sensor produces the “O”.

Activating the preferred [7] seven sensor simultaneously with the preferred [*] asterisk sensor produces the “p”, when followed by the activation of the preferred [*] asterisk sensor produces the “P”.

Activating the preferred [7] seven sensor simultaneously with the [0] zero sensor produces the “r”, when followed by the activation of the preferred [*] asterisk sensor produces the “R”.

Activating the preferred [7] seven sensor produces the “s”, when followed by the activation of the preferred [*] asterisk sensor produces the “S”.

Activating the preferred [8] eight sensor simultaneously with the preferred [*] asterisk sensor produces the “t”, when followed by the activation of the preferred [*] asterisk sensor produces the “T”.

Activating the preferred [8] eight sensor simultaneously with the [0] zero sensor produces the “u”, when followed by the activation of the preferred [*] asterisk sensor produces the “U”.

Activating the preferred [8] eight sensor produces the “v”, when followed by the activation of the preferred [*] asterisk sensor produces the “V”.

Activating the preferred [9] nine sensor simultaneously with the preferred [*] asterisk sensor produces the “w”, when followed by the activation of the preferred [*] asterisk sensor produces the “W”.

Activating the preferred [9] nine sensor simultaneously with the [0] zero sensor produces the “x”, when followed by the activation of the preferred [*] asterisk sensor produces the “X”.

Activating the preferred [9] nine sensor produces the “y”, when followed by the activation of the preferred [*] asterisk sensor produces the “Y”. Activating the preferred [*] asterisk sensor twice produces the backspace function.

In another alternative embodiment of a shiftable simultaneous two key activation data entry method, activating one of the [1] one through [9] nine sensors simultaneously with the preferred [*] asterisk sensor produces the first left position data character, with the [0] zero sensor produces the second middle position data character or with the preferred [#] pound sensor produces the third right position data character. Activating the preferred [*] asterisk sensor after producing a data character, produces an upper-case data character or a data character from a second set of data characters. One out of three data characters on the [1] one through [9] nine sensors is used more than the others. On the [2] two sensor the “a” is used more than the “b” or “c”, on the [3] sensor the “e” is used more than the “d” or “f”, on the [4] sensor the “i” is used more than the “g” or “h”, on the [5] sensor the “i” is used more than the “j” or “k”, on the [6] sensor the “o” is used more than the “m” or “n”, on the [7] sensor the “s” is used more than the “p” or “r”, on the [8] sensor the “t” is used more than the “u” or “v” and on the [9] sensor the “w” is used more than the “x” or “y”. Using only on key activation for the most used data character on the [1] one through [9] nine sensors and simultaneous two key activation for the other two least used data characters is another embodiment of the present invention.

Activating the preferred [1] one sensor one time produces the “.” period followed by a space. Activating the preferred [1] one sensor simultaneously with the preferred [*] asterisk sensor produces the “-” dash.

Activating the preferred [1] one sensor simultaneously with the [0] zero sensor produces the “q”, when followed by the activation of the preferred [*] asterisk sensor produces the “Q”.

Activating the preferred [1] one sensor simultaneously with the preferred [#] pound sensor produces the “z”, when followed by the activation of the preferred [*] asterisk sensor produces the “Z”.

Activating the preferred [2] two sensor produces the “a”, when followed by the activation of the preferred [*] asterisk sensor produces the “A”.

Activating the preferred [2] two sensor simultaneously with the [0] zero sensor produces the “b”, when followed by the activation of the preferred [*] asterisk sensor produces the “B”.

Activating the preferred [2] two sensor simultaneously with the preferred [#] pound sensor produces the “c”, when followed by the activation of the preferred [*] asterisk sensor produces the “C”.

Activating the preferred [3] three sensor simultaneously with the preferred [*] asterisk sensor produces the “d”, when followed by the activation of the preferred [*] asterisk sensor produces the “D”.

Activating the preferred [3] three sensor produces the “e”, when followed by the activation of the preferred [*] asterisk sensor produces the “E”.

Activating the preferred [3] three sensor simultaneously with the preferred [#] pound sensor produces the “f”, when followed by the activation of the preferred [*] asterisk sensor produces the “F”.

Activating the preferred [4] four sensor simultaneously with the preferred [*] asterisk sensor produces the “g”, when followed by the activation of the preferred [*] asterisk sensor produces the “G”.

Activating the preferred [4] four sensor simultaneously with the [0] zero sensor produces the “h”, when followed by the activation of the preferred [*] asterisk sensor produces the “H”.

Activating the preferred [4] four sensor produces the “i”, when followed by the activation of the preferred [*] asterisk sensor produces the “I”.

Activating the preferred [5] five sensor simultaneously with the preferred [*] asterisk sensor produces the “j”, when followed by the activation of the preferred [*] asterisk sensor produces the “J”.

Activating the preferred [5] five sensor simultaneously with the [0] zero sensor produces the “k”, when followed by the activation of the preferred [*] asterisk sensor produces the “K”.

Activating the preferred [5] five sensor produces the “l”, when followed by the activation of the preferred [*] asterisk sensor produces the “L”.

Activating the preferred [6] sensor simultaneously with the preferred [*] asterisk sensor produces the “m”, when followed by the activation of the preferred [*] asterisk sensor produces the “M”.

Activating the preferred [6] sensor simultaneously with the [0] zero sensor produces the “n”, when followed by the activation of the preferred [*] asterisk sensor produces the “N”.

Activating the preferred [6] sensor produces the “o”, when followed by the activation of the preferred [*] asterisk sensor produces the “O”.

Activating the preferred [7] seven sensor simultaneously with the preferred [*] asterisk sensor produces the “p”, when followed by the activation of the preferred [*] asterisk sensor produces the “P”.

Activating the preferred [7] seven sensor simultaneously with the [0] zero sensor produces the “r”, when followed by the activation of the preferred [*] asterisk sensor produces the “R”.

Activating the preferred [7] seven sensor produces the “s”, when followed by the activation of the preferred [*] asterisk sensor produces the “S”.

Activating the preferred [8] eight sensor produces the “t”, when followed by the activation of the preferred [*] asterisk sensor produces the “T”.

Activating the preferred [8] eight sensor simultaneously with the [0] zero sensor produces the “u”, when followed by the activation of the preferred [*] asterisk sensor produces the “U”.

Activating the preferred [8] eight sensor simultaneously with the preferred [#] pound sensor produces the “v”, when followed by the activation of the preferred [*] asterisk sensor produces the “V”.

Activating the preferred [9] nine sensor produces the “w”, when followed by the activation of the preferred [*] asterisk sensor produces the “W”.

Activating the preferred [9] nine sensor simultaneously with the [0] zero sensor produces the “x”, when followed by the activation of the preferred [*] asterisk sensor produces the “X”.

Activating the preferred [9] nine sensor simultaneously with the preferred [#] pound sensor produces the “y”, when followed by the activation of the preferred [*] asterisk sensor produces the “Y”. Activating the preferred [*] asterisk sensor twice produces the backspace function.

Alternatively, after the desired data character is produced by one of the [1] one through [9] nine sensors or in a simultaneous mode, activation of the [*] asterisk labeled sensor two, three or more times produces a second data character set, a third data character set or even more data characters sets. This alternative method of producing extra data character sets eliminates the production of the backspace function, but creates a second set of data characters, third set of data characters, etc.

While in the alphabetic mode, activating the [0] zero sensor produces a “ ” space.

While in the alphabetic mode, activating the [0] zero sensor twice produces a Tab function or Enter function.

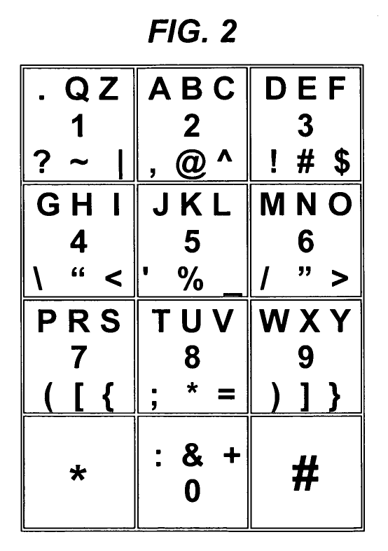

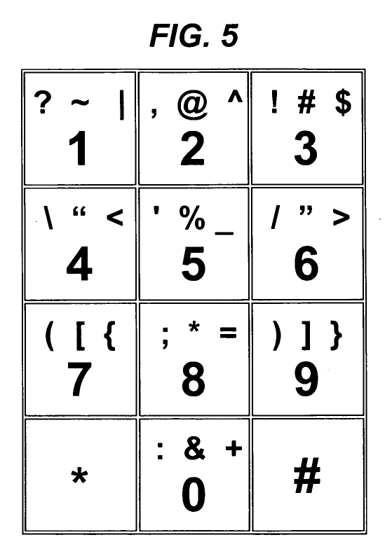

Referring to the preferred keypad labeling embodiment illustrated in FIG. 2 and the preferred keypad labeling embodiment for a refreshable display device illustrated in FIG. 5, activating the preferred [#] pound labeled sensor followed by the preferred [*] asterisk labeled sensor enters a punctuation/symbol mode. Activating one of the [1] one through [9] nine sensors or the [0] sensor, while in the punctuation/symbol mode produces a first left data character (punctuation mark or symbol), activating the preferred [*] asterisk sensor a second time followed by the activation of one of the [1] one through [9] nine sensors or the [0] sensor, while in the second punctuation/symbol mode produces a second middle data character (punctuation mark or symbol), activating the preferred [*] asterisk sensor a third time followed by the activation of one of the [1] one through [9] nine sensors or the [0] sensor, while in the third punctuation/symbol mode produces a third right data character (punctuation mark or symbol), activating the preferred [*] asterisk sensor a fourth time followed by the activation of one of the [1] one through [9] nine sensors or the [0] sensor, while in the punctuation/symbol mode produces a first left data character (punctuation mark or symbol) or a fourth data character (punctuation mark or symbol), etc.

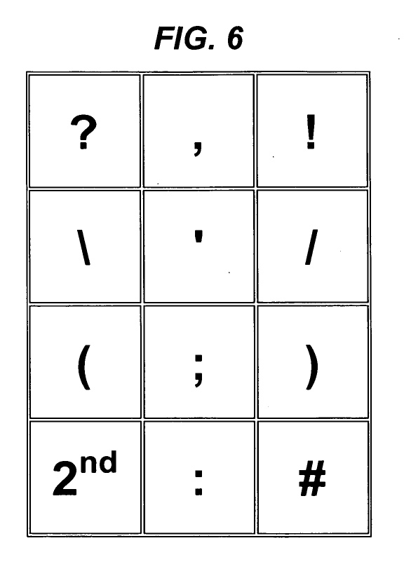

Referring to the preferred keypad labeling embodiment for a refreshable display device illustrated in FIG. 6, activating the preferred right [#] pound sensor followed by the activation of the preferred left [*] asterisk sensor, while in the alphabetic mode, produces the preferred “?” question mark followed by a space when the [1] sensor is activated, the preferred “,” comma followed by a space when the [2] sensor is activated, the preferred“!” exclamation mark followed by a space when the [3] sensor is activated, the preferred “\” backslash when the [4] sensor is activated, the preferred “'” apostrophe when the [5] sensor is activated, the preferred “/” slash when the [6] sensor is activated, the preferred “(” left parenthesis when the [7] sensor is activated, the preferred “;” semicolon followed by a space when the [8] sensor is activated, the preferred “)” right parenthesis when the [9] sensor is activated and the preferred “:” colon followed by a space when the [0] sensor is activated.

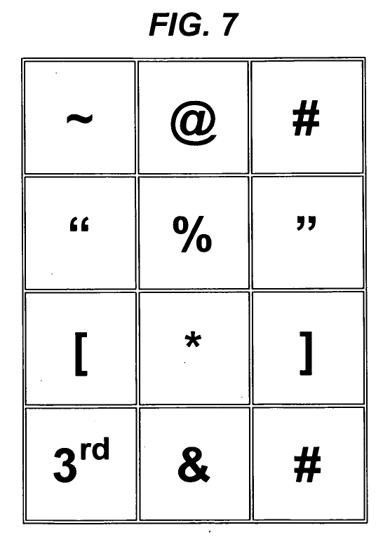

Referring to the preferred keypad labeling embodiment for a refreshable display device illustrated in FIG. 7, activating the preferred right [#] pound sensor followed by the activation of the preferred left [*] asterisk sensor two times, while in the alphabetic mode, produces the preferred “˜” tilde when the [1] sensor is activated, the preferred “@” at symbol when the [2] sensor is activated, the preferred “#” number sign when the [3] sensor is activated, the preferred ““” left quote when the [4] sensor is activated, the preferred “%” percent sign when the [5] sensor is activated, the preferred “”” right quote when the [6] sensor is activated, the preferred “[” left bracket when the [7] sensor is activated, the preferred “*” asterisk when the [8] sensor is activated, the preferred “]” right bracket when the [9] sensor is activated and the preferred “&” ampersand when the [0] sensor is activated.

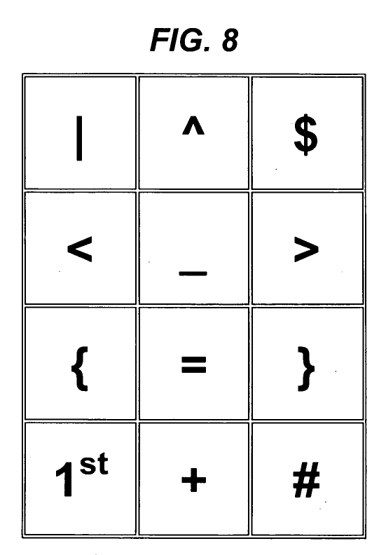

Referring to the preferred keypad labeling embodiment for a refreshable display device illustrated in FIG. 8, activating the preferred right [#] pound sensor followed by the activation of the preferred left [*] asterisk sensor three times, while in the alphabetic mode, produces the preferred “|” vertical line when the [1] sensor is activated, the preferred “̂” caret when the [2] sensor is activated, the preferred “$” dollar sign when the [3] sensor is activated, the preferred “<” less than when the [4] sensor is activated, the preferred “ ” underscore when the [5] sensor is activated, the preferred “>” greater than when the [6] sensor is activated, the preferred “{” left brace when the [7] sensor is activated, the preferred “=” equals when the [8] sensor is activated, the preferred “}” right brace when the [9] sensor is activated and the preferred “+” plus sign when the [0] sensor is activated.

Alternatively, simultaneously activating the preferred [#] pound labeled sensor and the preferred [*] asterisk labeled sensor enters a punctuation/symbol mode where activating one of the [1] one through [9] nine sensors or the [0] sensor produces a first left data character (punctuation mark or symbol). Activating the preferred [*] asterisk sensor followed by the activation of one of the [1] one through [9] nine sensors or the [0] sensor, while in the second punctuation/symbol mode produces a second middle data character (punctuation mark or symbol). Activating the preferred [*] asterisk sensor a second time followed by the activation of one of the [1] one through [9] nine sensors or the [0] sensor, while in the third punctuation/symbol mode produces a third right data character (punctuation mark or symbol). Activating the preferred [*] asterisk sensor a third time followed by the activation of one of the [1] one through [9] nine sensors or the [0] sensor, while in the punctuation/symbol mode produces a first left data character (punctuation mark or symbol) or a fourth data character (punctuation mark or symbol), etc.

Referring to the preferred keypad labeling embodiment for a refreshable display device illustrated in FIG. 6, simultaneously activating the preferred right [#] pound sensor and the preferred left [*] asterisk sensor, while in the alphabetic mode, produces the preferred “?” question mark followed by a space when the [1] sensor is activated, the preferred “,” comma followed by a space when the [2] sensor is activated, the preferred “!” exclamation mark followed by a space when the [3] sensor is activated, the preferred “\” backslash when the [4] sensor is activated, the preferred “'” apostrophe when the [5] sensor is activated, the preferred “/” slash when the [6] sensor is activated, the preferred “(” left parenthesis when the [7] sensor is activated, the preferred “;” semicolon followed by a space when the [8] sensor is activated, the preferred “)” right parenthesis when the [9] sensor is activated and the preferred “:” colon followed by a space when the [0] sensor is activated.

Referring to the preferred keypad labeling embodiment for a refreshable display device illustrated in FIG. 7, simultaneously activating the preferred right [#] pound sensor and the preferred left [*] asterisk sensor and then activating the preferred left [*] asterisk sensor, while in the alphabetic mode, produces the preferred “˜” tilde when the [1] sensor is activated, the preferred “@” at symbol when the [2] sensor is activated, the preferred “#” number sign when the [3] sensor is activated, the preferred ““” left quote when the [4] sensor is activated, the preferred “%” percent sign when the [5] sensor is activated, the preferred “”” right quote when the [6] sensor is activated, the preferred “[” left bracket when the [7] sensor is activated, the preferred “*” asterisk when the [8] sensor is activated, the preferred “]” right bracket when the [9] sensor is activated and the preferred “&” ampersand when the [0] sensor is activated.

Referring to the preferred keypad labeling embodiment for a refreshable display device illustrated in FIG. 8, simultaneously activating the preferred right [#] pound sensor and the preferred left [*] asterisk sensor and then activating the preferred left [*] asterisk sensor two times, while in the alphabetic mode, produces the preferred “|” vertical line when the [1] sensor is activated, the preferred “̂” caret when the [2] sensor is activated, the preferred “$” dollar sign when the [3] sensor is activated, the preferred “<” less than when the [4] sensor is activated, the preferred “ ” underscore when the [5] sensor is activated, the preferred “>” greater than when the [6] sensor is activated, the preferred “{” left brace when the [7] sensor is activated, the preferred “=” equals when the [8] sensor is activated, the preferred “}” right brace when the [9] sensor is activated and the preferred “+” plus sign when the [0] sensor is activated.

The alphabetic mode is automatically re-entered into after the punctuation mark or symbol is produced. The user must activate the preferred [#] pound sensor followed by the preferred [*] asterisk sensor to re-enter the punctuation/symbol mode or simultaneously activate the preferred [#] pound sensor and the preferred [*] asterisk sensor to re-enter the punctuation/symbol mode.

When a punctuation mark is produced, the punctuation mark automatically is followed by a space. Activating the preferred [*] asterisk sensor after the punctuation mark and space is produced, deletes the space after the punctuation mark. Activating the preferred [0] zero sensor after the period and space is produced, deletes the space after the period.

The 160 character phrase: “The razor-toothed piranhas of the genera Serrasalmus and Pygocentrus are the most ferocious freshwater fish in the world. In reality they seldom attack a human.” is used as the text message for the multi-tap world's record, found in the Guinness Book of World Records. The world's record for multi-tap data input into a phone keypad was obtained using prior art methods of data entry (Tegic T9 and Motorola's iTap). Tegic T9 and Motorola's iTap average more than two taps per character and both require more than 230 taps to produce the 160 character Guinness Book of World Records phrase.

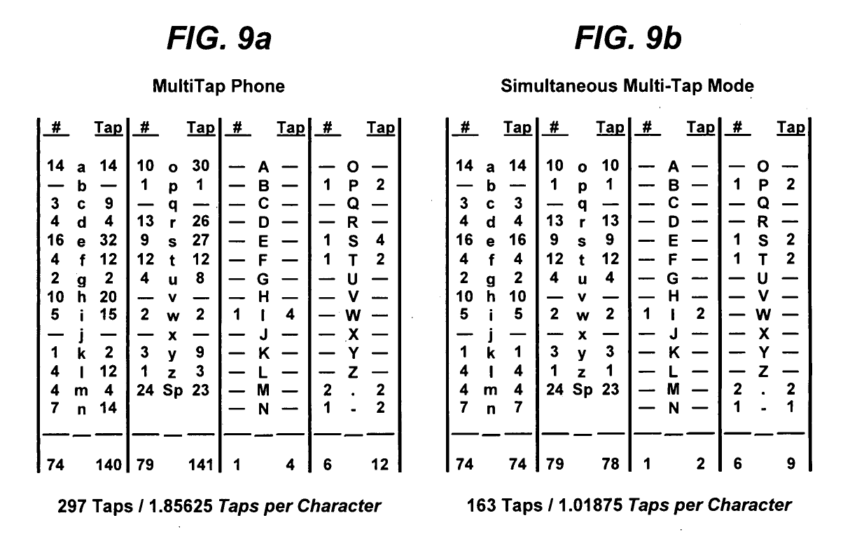

Referring to the table illustrated in FIG. 9a, the preferred embodiment of the present invention, using the multi-tap data entry method disclosed in this patent application, requires only 297 taps to produce the 160 character Guinness Book of World Records phrase “The razor-toothed piranhas of the genera Serrasalmus and Pygocentrus are the most ferocious freshwater fish in the world. In reality they seldom attack a human.”. This makes the invention disclosed in this patent application the world's fastest method of multi-tap data entry using twelve sensors.

The fastest prior art methods of sequential and/or simultaneous data entry into a twelve sensor phone device are found in U.S. Pat. No. 6,043,761, titled “Method of Using a Nine Key Alphanumeric Binary Keyboard Combined with a Three Key Keyboard Control Keyboard”, U.S. Pat. No. 6,184,803, titled “Nine Key Alphanumeric Binary Keyboard Combined with a Three Key Keyboard Control Keyboard and Combinational Control Means” and U.S. Pat. No. 6,232,892, titled “Method of Using a Nine Key Alphanumeric Binary Keyboard Combined with a Three Key Keyboard Control Keyboard”, and were all invented by the applicant of the invention found in the present patent application. By replacing the twelve sensor keypad labeling found in U.S. Pat. No. 6,043,761, U.S. Pat. No. 6,184,803 and U.S. Pat. No. 6,232,892 with the twelve sensor keypad labeling and control means found in the present patent application, the applicant has invented the fastest twelve sensor data entry method in the world.

Referring to the table illustrated in FIG. 9b, another preferred embodiment of the present invention, using the simultaneous data entry method disclosed in this patent application, requires only 163 taps to produce the 160 character Guinness Book of World Records phrase “The razor-toothed piranhas of the genera Serrasalmus and Pygocentrus are the most ferocious freshwater fish in the world. In reality they seldom attack a human.”. This makes the alternative simultaneous data entry embodiment of the present invention much faster than the 297 tap multi-tap data entry method and the fastest twelve sensor data entry method in the world.

The world's smallest keyboards and the fastest prior art methods of sequential data entry into a nine sensor phone device are found in U.S. patent application Ser. No. 12/202,702, titled “Nine Sensor Data Entry Keyboard and Control Means” and U.S. patent application Ser. No. 12/235,984, titled “World's Smallest Keyboard and Control Means”, and were both invented by the applicant of the invention found in the present patent application. By adding three sensors below the nine sensor keypads found in U.S. Patent application Ser. No. 12/202,702 and U.S. Patent application Ser. No. 12/235,984, and replacing their keypad labeling with the keypad labeling and control means found in the present patent application, the applicant has invented the smallest keyboards in the world using the fastest twelve sensor data entry method in the world.

Although the previously described preferred sensor labeling embodiment for the production of punctuation and symbols is being labeled described in the easiest mnemonic arrangement, a latitude of modification, change, and substitution is intended. One example of this would be the use of other types of punctuation used in other languages or the user of a device programmed with the preferred embodiments found in this patent application decided to reprogram the location or sequence of the data characters or the data characters used. Another example would be; a user of a device programmed with the preferred embodiments found in this patent application, used the device to enter URL website addresses. They would not want spaces automatically inserted after the colon or period punctuation marks. The device could also be preprogrammed not to automatically include spaces inserted after the colon or period punctuation marks when entering a URL website address or when entering any type of data into a device. A device could also be programmed, while in a punctuation mode, to include a fourth set of punctuation and symbols with up to ten extra data characters on ten sensors, etc.

These and other features of the present invention will be more fully understood by referencing the drawings.

### ADVANTAGES OF THE PRESENT INVENTION

In summary, the present invention, previously described, has provided the fastest twelve key data entry methods, in the previously disclosed multi-tap data entry embodiment or in the multiple simultaneous data entry embodiments, which all require less taps than all the existing prior art.

The present invention preferably embodies a twelve sensor keypad with twelve data characters on twelve sensors, a twelve sensor keypad with preferably three extra data characters on nine numbered sensors, a twelve sensor keypad with preferably six extra data characters on nine numbered sensors, a twelve sensor keypad with preferably six extra data characters on nine numbered sensors and preferably three data characters on a tenth sensor, a shift function is provided after a data character is produced in an alphabetic mode, a backspace function is provided while in a number mode or in an alphabetic mode, a punctuation and symbol mode is provided with complete punctuation and symbols, where a space is automatically produced after a punctuation mark.

While the present invention disclosed has been described with reference to the preferred embodiments thereof, a latitude of modification, change, and substitution is intended in the foregoing disclosure, and in some instances, some features of the invention will be employed without a corresponding use of the inventions other features. Accordingly, it will be appreciated by those having an ordinary skill in the art that various modifications can be made to the system of the invention and it is appropriate that the description and appended claims are construed broadly and in a manner consistent with the spirit and scope of the invention herein without departing from the spirit and scope of the invention as a whole.

1. A keyboard for entering alphanumeric data, comprising at least twelve sensors, wherein:
a) activating one of ten numbered sensors produces one of the numbers 1, 2, 3, 4, 5, 6, 7, 8, 9 or 0;
b) activating an eleventh sensor at least once exits a numeric mode and enters an alphabetic mode;
c) activating a first, second, third, fourth, fifth, sixth, seventh, eighth or ninth sensor at least once, in said alphabetic mode, produces one of at least three data characters of a first set of data characters; and
d) activating a twelfth sensor twice, in said alphabetic mode, re-enters said numeric mode.

2. The keyboard of claim 1, in said numeric mode, wherein activating said twelfth sensor deletes the last entered number.

3. The keyboard of claim 1, in said alphabetic mode, wherein activating said first, second, third, fourth, fifth, sixth, seventh, eighth or ninth sensor at least once produces one of at least three data characters of said first set of data characters, followed by the activation of said twelfth sensor, enters one of at least three data characters of said first set of data characters.

4. The keyboard of claim 1, in said alphabetic mode, wherein:
a) activating said first sensor produces a period “.”, q or z;
b) activating said second sensor produces an a, b or c;
c) activating said third sensor produces a d, e or f;
d) activating said fourth sensor produces a g, h or i;
e) activating said fifth sensor produces a j, k or l;
f) activating said sixth sensor produces a m, n or o;
g) activating said seventh sensor produces a p, r or s;
h) activating said eighth sensor produces a t, u or v; and
i) activating said ninth sensor produces a w, x or y.

5. The keyboard of claim 1, in said alphabetic mode, wherein activating said first, second, third, fourth, fifth, sixth, seventh, eighth or ninth sensor at least once produces one of at least three data characters of said first set of data characters and is followed by the activation of said eleventh sensor produces one of at least three data characters of a second set of data characters.

6. The keyboard of claim 5, in said alphabetic mode, wherein activation of said eleventh sensor, after producing one of at least three data characters of said first set of data characters, produces an upper-case letter.

7. The keyboard of claim 1, in said alphabetic mode, wherein activation of said eleventh sensor twice produces the backspace function.

8. The keyboard of claim 1, wherein activating said twelfth sensor combined with the activation of said eleventh sensor enters a punctuation and symbol mode.

9. The keyboard of claim 8, wherein:
a) activation of said eleventh sensor two times enters a second punctuation and symbol mode; and
b) activation of said eleventh sensor three times enters a third punctuation and symbol mode.

10. A keyboard for entering alphanumeric data, comprising at least twelve sensors, wherein:
a) activating one of ten numbered sensors produces one of the numbers 1, 2, 3, 4, 5, 6, 7, 8, 9 or 0;
b) activating an eleventh sensor at least once exits a numeric mode and enters an alphabetic mode;
c) activating one of nine sensors, of a first set of sensors, combined with one of three sensors, of a second set of sensors, produces one of three data characters, of a first set of data characters; and
d) activating a twelfth sensor twice, in said alphabetic mode, re-enters said numeric mode.

11. The keyboard of claim 10, wherein activating one of nine sensors, of said first set of sensors, simultaneously with one of three sensors, of a second set of sensors, produces one of three data characters, of said first set of data characters.

12. The keyboard of claim 10, in said numeric mode, wherein activating said twelfth sensor deletes the last entered number.

13. The keyboard of claim 10, in said alphabetic mode, wherein activating said first, second, third, fourth, fifth, sixth, seventh, eighth or ninth sensor at least once produces one of at least three data characters of said first set of data characters, followed by the activation of said twelfth sensor, enters one of at least three data characters of said first set of data characters.

14. The keyboard of claim 10, in said alphabetic mode, wherein:
a) activating said first sensor produces a period “.”, q or z;
b) activating said second sensor produces an a, b or c;
c) activating said third sensor produces a d, e or f;
d) activating said fourth sensor produces a g, h or i;
e) activating said fifth sensor produces a j, k or l;
f) activating said sixth sensor produces a m, n or o;
g) activating said seventh sensor produces a p, r or s;
h) activating said eighth sensor produces a t, u or v; and
i) activating said ninth sensor produces a w, x or y.

15. The keyboard of claim 10, in said alphabetic mode, wherein activating said first, second, third, fourth, fifth, sixth, seventh, eighth or ninth sensor at least once produces one of at least three data characters of said first set of data characters and is followed by the activation of said eleventh sensor produces one of at least three data characters, of a second set of data characters.

16. The keyboard of claim 15, in said alphabetic mode, wherein activation of said eleventh sensor produces, after producing one of at least three data characters of said first set of data characters, an upper-case letter.

17. The keyboard of claim 10, in said alphabetic mode, wherein activation of said eleventh sensor twice produces the backspace function.

18. The keyboard of claim 10, wherein simultaneously activating said twelfth and said eleventh sensor enters a punctuation and symbol mode.

19. The keyboard of claim 18, wherein:
a) activation of said eleventh sensor two times enters a second punctuation and symbol mode; and
b) activation of said eleventh sensor three times enters a third punctuation and symbol mode.

20. A keyboard for entering alphanumeric data, comprising at least twelve sensors, wherein:
a) activating one sensor of a first set of nine sensors in a number mode produces the numbers one through nine or activating one sensor of a first set of nine sensors in an alphabetic mode produces one of at least three data characters, of a first set of data characters;
b) activating a first sensor, of a second set of three sensors, after producing said one of three data characters, of said first set of data characters, on said first set of nine sensors, produces a second data character, of a second set of data characters;
c) activating a second sensor, of said second set of three sensors, while in said alphabetic mode, produces a space; and
d) activating a third sensor in said alphabetic mode, of said second set of three sensors, produces an enter function.

21. The keyboard of claim 20, in said alphabetic mode, wherein activating said first sensor, of said second set of three sensors, twice, produces a backspace function.

22. The keyboard of claim 20, in said alphabetic mode, wherein activating said third sensor, of said second set of three sensors, twice, enters a number mode.

23. The keyboard of claim 20, in said alphabetic mode, wherein activating said third sensor and said first sensor, of said second set of three sensors, enters a punctuation mode.

24. The keyboard of claim 20, in said alphabetic mode, wherein activating one of said first set of nine sensors simultaneously with one of said second set of three sensors, produces one of at least three data characters, of said first set of data characters.
